(19) United States
(12) Patent Application Publication
(10) Pub. No.: US 2010/0251062 A1
(43) Pub. Date: Sep. 30, 2010

(54) ENCODING METHOD AND TRANSMISSION DEVICE

(75) Inventors: Chao Chen, Beijing (CN); Hao Jiang, Beijing (CN); Ming Xu, Beijing (CN); Kenichi Kuri, Kanagawa (JP); Akihiko Nishio, Kanagawa (JP)

Correspondence Address: Dickinson Wright PLLC;James E. Ledbetter, Esq., International Square, 1875 Eye Street, N.W., Suite 1200, Washington, DC, 20006, US

(73) Assignee: PANASONIC CORPORATION, OSAKA (JP)

(21) Appl. No.: 12/741,752

(22) PCT Filed: Nov. 7, 2008
(86) PCT No.: PCT/JP2008/003240

§ 371 Date: May 6, 2010

(30) Foreign Application Priority Data
Nov. 9, 2007 (CN) 200710186026.X

(51) Int. Cl. H03M 13/05; G06F 11/10

(52) U.S. Cl. 714/752; 714/E11.032

(57) ABSTRACT

Provided is an encoding method including: a step of extending a bidiagonal line of a basic matrix of m rows and n columns in the direction of a bidiagonal line according to an encoding ratio 1/k of the spread code (wherein k=3, 4, 5, . . . , k0) set in the LDPC code inspection matrix so as to constitute an extended matrix of the bidiagonal line structure; a step of moving a first non-zero element of the parity bit portion in the (i*m+1)-th row to the (n−m+1)-th column (wherein i=1, 2, . . . , k0−2) leftward along the row; a step of calculating the parity bit of the (n−m+1)-th column by using a first inspection relationship as a start factor; and a step of simultaneously calculating parity bits of a plurality of groups by the recursive encoding method by using the inspection relationship moved leftward to the (n−m+1)-th column.

### TECHNICAL FIELD

The present invention relates to a method of reducing the delay of encoding time by improving the degree of parallelism of encoding. In particular, the present invention relates to a method of introducing a plurality of parallel encoding processes for a Quasi-Cyclic low density parity-check code having a dual diagonal structure, and substantially matching the encoding time of an extended code with the encoding time of the base code without making the encoding time of the extended code increase linearly in accordance with the decrease in the coding rate.

### BACKGROUND ART

In Recent years, radio communication systems have been developed to allow very high speed data transmission. Therefore, there is a demand for a more efficient encoding method than a conventional encoding method. LDPC (Low Density Parity-Check) codes are one class of strong forward error correcting codes which have attracted attention in recent ten years. LDPC codes, which have a very long codeword length, is approaching the Shannon limit, and is therefore considered as an effective alternative technique of turbo codes, and there is a high possibility that these LDPC codes are used for the next generation mobile communication and space communication.

LDPC codes are one of codes defined based on a parity cheek matrix, and was proposed by Gallager in 1962. Also, an LDPC code has characteristics of including a small number j (j≧1) of 1's in each column of a check matrix and a small number k (k>j) of 1's in each row of the check matrix. Gallager proved that the general minimum distance of a codeword, which was acquired by encoding information using that check matrix, increased linearly following the increase in the codeword length, and the general rate of decoding errors in a BSC (Binary Symmetric Channel) decreased on an exponential scale in accordance with the codeword length.

Also, in 1981, Tanner proposed a concept of illustrating a codeword using a diagram model and associated an LDPC code check matrix with a bipartite graph comprised of two bidirectional nodes formed with rows and columns of a check matrix, referred to as “Tanner graph,” In a Tanner graph, each check matrix row is referred to as “check node” and each check matrix column is referred to as “variable node.” The variable nodes and check nodes in a Tanner graph are connected according to the arrangement of 1's in the check matrix, and decoding processing is performed by iteratively executing information transmission between connected nodes. LDPC codes represented by a Tanner graph can parallelize decoding processing, thereby significantly reducing the complexity of decoding processing. Further, Tanner has analyzed two information transmission algorithms of the min-sum algorithm and sum-product algorithm in detail and proved the optimality of the min-sum decoding algorithm and sum-product decoding algorithm based on a Tanner graph having a finite length and no loop. However, the Tanner graph actually adopts a random graph structure and unavoidably has a loop of a short loop length (hereinafter “small loop”). An occurrence of such a short loop may cause overlapping transmission of decoding information, and, consequently, it is not possible to satisfy the presumption of independence between decoding information (e.g. messages) in iterative decoding process of LDPC coding, which gives a negative influence on the convergence performance of transmission decoding algorithms.

In 1996, Mackay and Spielman rediscovered that LDPC code provided performance as good as Turbo codes, and, when the codeword length was longer, provided better performance than Turbo code. By this means, LDPC codes became a new target of research and attracted wide attention.

Rechardson et al. started out with a study of a group of LDPC code structures that satisfy certain restriction, established the density evolution theory of infinite-length LDPC codes and provided important reference information to form finite-length LDPC codes. From this study, it was discovered that there was a threshold for decoding processing (i.e. decoding threshold) in the iterative transmission process of decoding information. To be more specific, Rechardson et al. discovered that it was possible to make the error rate of decoding information closer to zero by performing iterative decoding in the case where the signal to noise ratio was greater than a decoding threshold, and that, in the case where the signal to noise ratio was less than the decoding threshold, the error rate converged to a certain error rate, regardless of how long the codeword length of an adopted LDPC code was and how many times iterative decoding was performed. Also, Richardson et al. applied the central limit theorem and proved that the decoding threshold of a Tanner graph having a finite length, random graph structure and loop, were approximated to the decoding threshold of a Tanner graph having no loop. Accordingly, by accurately calculating the decoding threshold of LDPC code on a Tanner graph without loops based on the density evolution theory established on the Tanner graph without loops, and analyzing the convergence conditions of that decoding, it is possible to approximately estimate the performance of LDPC codes in a Tanner graph with a loop. Also, as proved by studies, the magnitude of decoding threshold closely relates to structure parameters of LDPC codes, an irregular LDPC code designed with optimal degree distribution can improve the decoding threshold, and therefore it is possible to use the density evolution theory to optimize LDPC code design.

An LDPC code configuration is based on two main rules for the purpose of removing small loops and allowing fast encoding.

One framework relates to an LDPC code configuration in which small loops are removed as much as possible based on an LDPC code having a random structure. Methods of forming that LDPC code include, for example, the progressive edge growth (“PEG”) method proposed by Hu Xiaoyu. This forming method is the method of preventing small loops as much as possible and increasing the loop length of loops in a Tanner graph of LDPC codes. An LDPC code formed by this method is suitable to a code having a random structure. Also, Tian Tao et al. proposed a Viterbi-like algorithm for selectively removing small loops, increasing the size of the stopping set and reducing the code error rate. The Viterbi-like algorithm analyzes the relationships between loops, stopping sets and their related columns in a check matrix (i.e. linear correlation columns) for LDPC codes, analyzes a coding performance restriction in the message transmission algorithm and measures the connection characteristics of a Tanner graph for the LDPC code by extrinsic message degree.

The other framework relates to a method of forming practical LDPC code, which has a certain algebraic structure and allows fast encoding, based on the algebraic theory. As a recent major achievement, there is finite geometric LDPC code based on a finite geometric structure. Finite geometric LDPC code removes loops with a loop length of 4 (i.e. loops of the shortest loop length) in a Tanner graph, so that it is possible to realize linear time encoding using a simple feedback shift register. Finite geometric LDPC code has a relatively good minimum distance. For example, in the case of a high coding rate and long codeword length (i.e. long code) in an AWGN (Additive White Gaussian Noise) communication path, the distance of the iterative decoding algorithm is only 0.4 dB from the Shannon limit.

Also, Tanner et al. designed a QC (Quasi-Cyclic) LDPC code. A QC LDPC code check matrix is formed with a cyclic matrix, which gives QC characteristics to the QC LDPC code, and therefore can realize effective encoding. Also, the algebraic structure of QC LDPC code is effective for realizing a VLSI circuit. Based on such characteristics, Tanner formed an LDPC convolutional code using a QC LDPC code cyclic matrix. A middle or short codeword length provides performance equivalent to regular codes having a random structure, and, a long codeword length (i.e. long code) provides performance slightly inferior to codes having a random structure.

With dramatic development of the LDPC code theory, process in practical use of LDPC codes is promoted. According to the IEEE 802.16e standard, which is a radio communication standard, an LDPC code is one of encoding modulation schemes combining encoding and modulation. Further, the IEEE802.16e standard adopts a QC LDPC code structure (with a codeword length from 576 to 2304 and a coding rate of 1/2, 2/3, 3/4 or 5/6) and divides multiplication of a large-size matrix into multiplication of small-size matrixes in parallel, thereby solving a problem of increasing the complexity of encoding of LDPC codes.

Also, encoded bits in an LDPC codeword provide different error protection characteristics. That is, encoded bits in an LDPC codeword provide different noise robustness capabilities. The currently proposed classification of LDPC encoded bits is performed based on the column degree of each encoded bit in an LDPC code check matrix. For example, Non-Patent Document 1 and Non-Patent Document 2 disclose documents relating to encoded bit classification.

FIG. 1 shows row degrees and column degrees defined in an LDPC code check matrix. In FIG. 1, the number of non-zero elements in each row or column of the check matrix represents the row degree of each row or the column degree of each column. For example, as shown in FIG. 1, the column degrees of the first to twelfth columns are 3, 3, 3, 3, 2, 3, 2, 2, 1, 1, 1 and 1, in order. According to the disclosure of Non-Patent Document 1, encoded bits matching a column of large column degree provide higher error correcting capability, and therefore it is preferable to map the encoded bits to bit positions in which the protection performance represented by a constellation is lower in a bit sequence. By this means, it is possible to improve encoding modulation performance, taking into account both the noise robustness capability and the encoding modulation gain of LDPC codes. Here, although such a classification method is simple and intuitive, a classification effect is not ideal for LDPC codes in which the column degrees vary little. Therefore, to satisfy the requirements of equivalent encoding modulation, in many cases, some encoded bits need to be selected in a random manner and classified roughly, which lacks accuracy.

FIG. 2 shows a Tanner graph supporting the LDPC code check matrix shown in FIG. 1. A linear code such as an LDPC code is represented as a Tanner graph (also referred to as “bipartite graph”) as shown in FIG. 2 and expressed by G={V∪C, E}. Here, set V is comprised of variable nodes, and these variable nodes correspond to encoded bits, that is, the columns of the LDPC code check matrix. Also, set C is comprised of check nodes, and these check nodes correspond to parity check equations, that is, the rows of the LDPC code check matrix. Also, set E is comprised of a plurality of edges connecting between variable nodes and check nodes. In the Tanner graph, if an encoded bit corresponding to a variable node relates to a parity check equation represented by a given check node, the row element corresponding to the check node is not “0” (i.e. non-zero element) in the column vector corresponding to that encoded bit in the check matrix. For example, the elements of the second, fifth and ninth columns of the fifth row in the LDPC code check matrix shown in FIG. 1 are not “0.” Therefore, in the Tanner graph of the LDPC code shown in FIG. 2 supporting FIG. 1, check node 5 is connected to variable nodes 2, 5 and 9 using edges. Also, the number of edges connected to a node will be referred to as the degree of the node. Therefore, as shown in FIG. 2, encoded bits corresponding to the columns of an LDPC code check matrix are represented as variable nodes in a Tanner graph, and parity check equations corresponding to the rows of the check matrix are represented as check nodes. According to the ongoing studies about the performance of LDPC encoded bits, the error performance of LDPC encoding is described primarily based on a Tanner graph.

Encoding is highly complex in LDPC codes. For example, the complexity of encoding increases in direct proportion to a square of the codeword length. Rechardson et al. proposed a method of dividing a check matrix into sub-matrixes to reduce the complexity of encoding. In the method of dividing a check matrix into sub-matrixes, first, a base matrix of in rows and n columns with a lower rank is defined. Further, by extending the base matrix using sub-matrixes of rank z×z upon actual encoding, a (m×z)×(n×z) check matrix (hereinafter “extended matrix”) used upon actual encoding is acquired. Each element of the base matrix is formed with a z×z sub-matrix. By extending the same base matrix according to the magnitude of z, it is possible to acquire a pair of LDPC codes having the same coding rate and different codeword lengths. Here, element “0” represents a z×z all-zero sub-matrix, other elements represent a sub-matrix acquired by cyclically shifting the columns of the z×z identity matrix based on the value indicated by {p(f, i, j)}. The value of z is equivalent to extended element z_{f}, (fε[0, 18]) defined in the standard. Element “1” in the matrix represents the identity matrix that is not subject to cyclic shifting, and other cyclically shifted values {p(f, i, j)} are calculated according to following equation 1 using equivalent extended element z_{f} and elements that are not “0” or “1” in the matrix (e.g. see Non-Patent Document 3).

$$\begin{matrix}[ 1 ] & \\ \{ p ( f , i , j ) \} = \{ \begin{matrix}p ( i , j ) , & p ( i , j ) \leq 0 \\ ⌊ \frac{p ( i , j ) {z}_{f}}{{z}_{0}} ⌋ , & p ( i , j ) > 0\end{matrix} & ( Equation 1 )\end{matrix}$$

As described above, according to the values of z, it is possible to acquire one systematic codeword of a discrete codeword length. The elements of the first to fourth columns in FIG. 1 correspond to systematic bits and represent the number of information bits. Also, the elements of the fifth to twelfth columns in FIG. 1 correspond to parity bits. As shown in FIG. 3, Li. Ping et al. proposed a semi-random LDPC code in which a part corresponding to the parity hits in a check matrix adopts a dual diagonal structure (or referred to as “zig-zag structure”). Afterward, this dual diagonal structure is applied to a QC LDPC code based on blocking.

Also, rate matching methods, which are usually used upon designing an LDPC code, include “shortening,” “puncturing” and “extension” of a cheek matrix. According to IEEE802.16, different check matrixes arc used for different coding rates without using the above-noted three rate matching methods, and, consequently, a problem arises that the flexibility of rate matching lacks. Therefore, with 3GPP LTE (3rd Generation Partnership Project Long Term Evolution), studies were conducted to perform rate matching by shortening and puncturing instead of providing different check matrixes for different coding rates. Of the three types of rate matching methods, the two types of rate matching methods of shortening and extension are methods for reducing the coding rate of a codeword, and puncturing is a method for increasing the coding rate of a codeword.

The rate matching by shortening is a method for adding some 0's (i.e. the “0” bits) to the head of information and performing encoding using the original check matrix (i.e. base matrix). Upon transmitting a codeword, the “0” bits added to perform rate matching are not transmitted. FIG. 4 shows the rate matching method by shortening. As shown in FIG. 4, first, information with some 0's added to that head is encoded using a check matrix to form the systematic bits and parity bits in the information. Finally, by removing the “0” bits added to the head from the transmission codeword, transmission bits are shortened.

With the rate matching by puncturing, by not transmitting part of the parity bits in a codeword acquired by encoding, the coding rate of transmission bits is increased. FIG. 5 shows the rate matching method by puncturing. As shown in FIG. 5, information is encoded to form systematic bits and parity bits. Further, by puncturing bits indicated by the “x” symbols and not transmitting them, transmission bits are shortened.

With the rate matching by extension, parity bits are increased to change the original check matrix (i.e. base matrix) to decrease the coding rate. FIG. 6 shows the rate matching method by extension. As shown in FIG. 6, information is encoded to form systematic bits and parity bits. Further, by newly adding parity bits after the systematic bits and parity bits, transmission bits are extended to decrease the coding rate.

Here, upon using an LDPC code acquired by encoding with a base matrix as a base code and adopting the base code of a medium coding rate, it is possible to increase the coding rate by puncturing and decrease the coding rate by shortening or extension. According to an existing result, upon using an LDPC code of a coding rate of 1/2 as a base code and decreasing the coding rate to 1/3 by shortening, the systematic bits are removed, and, consequently, the performance is inferior to Turbo codes under the same conditions. Therefore, upon rate matching from a medium coding rate to a lower coding rate, the method of adding parity bits to the base code by extension is effective.

Also, a base code has a dual diagonal structure and a QC structure. For example, assume that the base code adopts the configuration shown in FIG. 7 (in FIG. 7, an LDPC code of coding rate R=1/2 is used as the base code). Also, as a method of extension, as shown in FIG. 7, the base matrix is extended to the check matrix (extended matrix) acquired by directly extending a dual diagonal structure (i.e. zig-zag structure) in a part corresponding to the parity bits in the base matrix along a dual diagonal.

### Non-Patent Document I: Yan Li, William E. Ryan, “Bit-Reliability Mapping in LDPC-Coded Modulation Systems”, 2005, “IEEE Communications Letters, VOL. 9, No. 1, January 2005 1”

Non-Patent Document 2: Rahnavard, N., Fekri, F. “Unequal error protection using low-density parity-check codes”, 2004, “International Symposium on Information Theory 2004. Proceedings. 27 June-2 Jul. 2004 Page(s):449”
Non-Patent Document 3: IEEE Std. 802.16e—2005

### DISCLOSURE OF INVENTION

### Problems to be Solved by the Invention

An LDPC code adopts a recursive scheme for encoding processing. For example, after the parity bit corresponding to the j-th column is calculated, it is possible to start the calculation of the parity bit corresponding to the (j+1)-th column. Therefore, parity bits are increased by extension, and, consequently, the time required for encoding processing (i.e. encoding time) increases. Thus, the encoding time increased based on recursive encoding, that is, delay time increases in direct proportion to the increase of parity bits by extension. FIG. 8 shows relationships between encoding time and generated parity bits in parts corresponding to extended parity bits having a dual diagonal structure (i.e. parts corresponding to the seventh to twenty-fourth columns shown in FIG. 7). As shown in FIG. 8, encoding time increases linearly in accordance with the increase of parity bits. Accordingly, from this perspective, recursive encoding is not obviously suitable to extension processing of realizing a low coding rate.

It is therefore an object of the present invention to provide an encoding method and transmitting apparatus for reducing delay due to the increase in encoding time by improving the degree of parallel encoding of a QC LDPC code having a dual diagonal structure (i.e. zig-zag structure), substantially matching the encoding time of an extended LDPC code with the encoding time of the base code, and thereby solving a problem of increasing encoding time linearly in accordance with the decrease in the coding rate.

### Means for Solving the Problem

The encoding method according to an aspect of the present invention includes the steps of: extending a dual diagonal structure of a base matrix of m rows and n columns along a dual diagonal, based on a coding rate 1/k of an extended code (where k=3, 4, 5, . . . , k0 holds, and where 1/k0 is a minimum coding rate of the extended code) set in a check matrix of a low density parity check code, to form an extended matrix having the dual diagonal structure; shifting a first non-zero element of a parity bit part in a (i*m+1)-th (where i=1, 2, . . . , k0−2) row leftward to a (n−m+1)-th column along that row; calculating a parity bit in the (n−m+1)-th column using a first check relationship as a key factor; and calculating parity bits in a plurality of groups simultaneously in parallel by a recursive encoding method, based on check relationships of the non-zero elements shifted leftward to the (n−m+1)-th column.

The transmitting apparatus according to an aspect of the present invention employs a configuration having: an encoding section that performs low density parity check encoding of transmission data using a check matrix of a low density parity check code, to acquire a codeword comprised of systematic bits and parity bits; and a transmitting section that transmits the codeword, where the encoding section includes: extending a dual diagonal structure of a base matrix of m rows and n columns along a dual diagonal, based on a coding rate 1/k of an extended code (where k=3, 4, 5, . . . , k0 holds and 1/k0 is a minimum coding rate of the extended code) set in the check matrix of the low density parity check code, to form an extended matrix having the dual diagonal structure; shifting a first non-zero element of a parity bit part in a (i*m+1)-th (where i=1, 2, . . . , k0−2) row leftward to a (n−m+1)-th column along that row; calculating a parity bit in the (n−m+1)-th column using a first check relationship as a key factor; and calculating parity bits in a plurality of groups simultaneously in parallel by a recursive encoding method, based on check relationships of the non-zero elements shifted leftward to the (n−m+1)-th column.

### ADVANTAGEOUS EFFECT OF THE INVENTION

According to the present invention, by introducing a plurality of encoding processes in parallel for an LDPC code having a dual diagonal structure, it is possible to change the structure of an extended matrix and calculate parity bits in a plurality of groups at the same time. Therefore, it is possible to substantially match the eventual encoding time with the encoding time of the base code before extension. Also, the advantage provided by the extension method of the present invention becomes significant in accordance with the decrease in the coding rate.

### BRIEF DESCRIPTION OF DRAWINGS

FIG. 1 shows row degrees and column degrees defined by an LDPC code check matrix;

FIG. 2 shows a Tanner graph for LDPC encoding;

FIG. 3 shows an LDPC check matrix having a zig-zag structure;

FIG. 4 shows a method of reducing the coding rate of transmission bits by shortening;

FIG. 5 shows a method of increasing the coding rate of transmission bits by puncturing;

FIG. 6 shows a method of decreasing the coding rate of transmission bits by extending a check matrix;

FIG. 7 shows an LDPC check matrix directly extending a dual diagonal structure;

FIG. 8 shows relationships between the encoding time and generated parity bits upon direct extension;

FIG. 9 is a block diagram showing the configuration of a transmitting apparatus according to an embodiment of the present invention;

FIG. 10 is a block diagram showing the configuration of a receiving apparatus according to an embodiment of the present invention;

FIG. 11 shows a check matrix acquired by directly extending a dual diagonal structure, according to an embodiment of the present invention;

FIG. 12 shows relationships between the encoding time and generated parity bits upon direct extension, according to an embodiment of the present invention;

FIG. 13A shows a state where an identity submatrix is replaced using a submatrix having a dual diagonal structure, according to an embodiment of the present invention;

FIG. 13B shows a submatrix having a dual diagonal structure according to an embodiment of the present invention;

FIG. 13C shows an identity submatrix according to an embodiment of the present invention;

FIG. 13D shows an all-zero submatrix according to an embodiment of the present invention;

FIG. 14 shows the structure of an extended matrix after a base code is changed in the case of bidirectional encoding, according to another embodiment of the present invention;

FIG. 15 shows relationships between the encoding time and generated parity bits upon direct extension, according to another embodiment of the present invention; and

FIG. 16 is a flowchart showing encoding processing of a QC LDPC code having a dual diagonal structure according to an embodiment of the present invention.

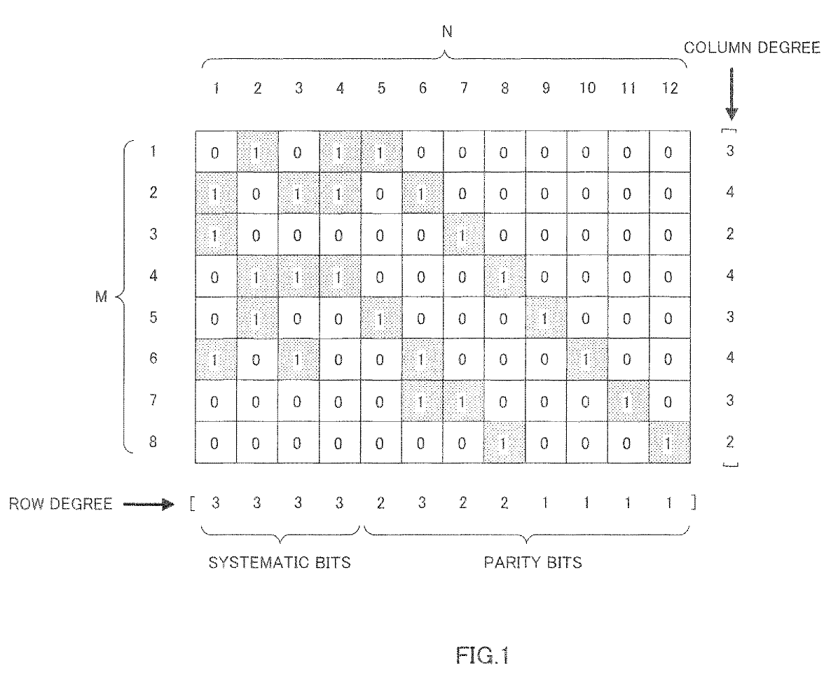

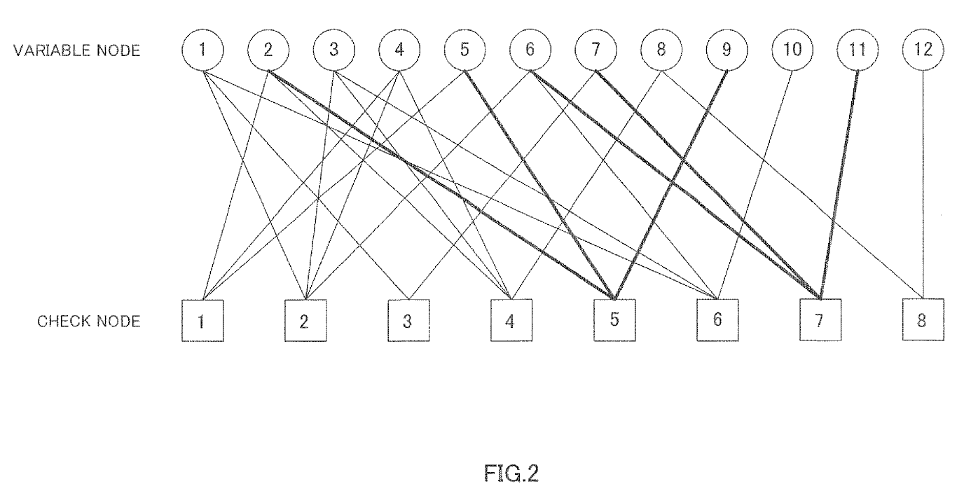

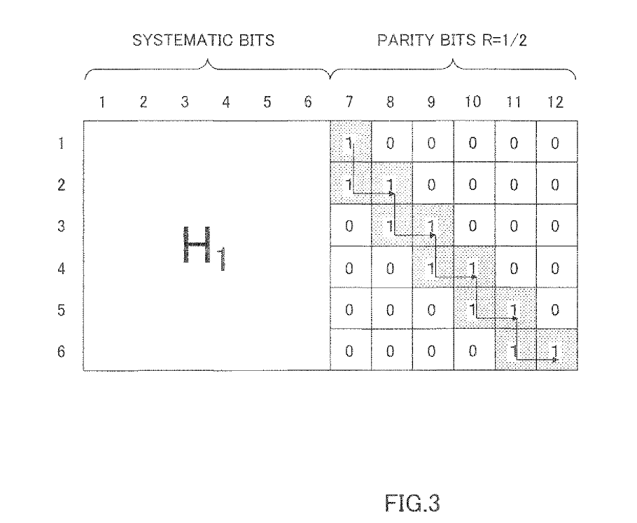

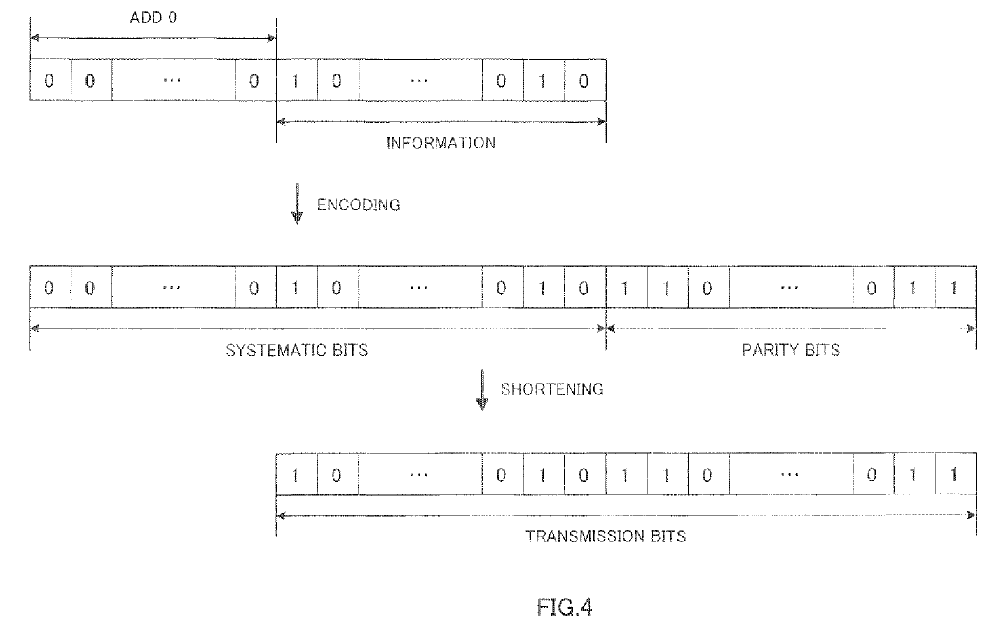

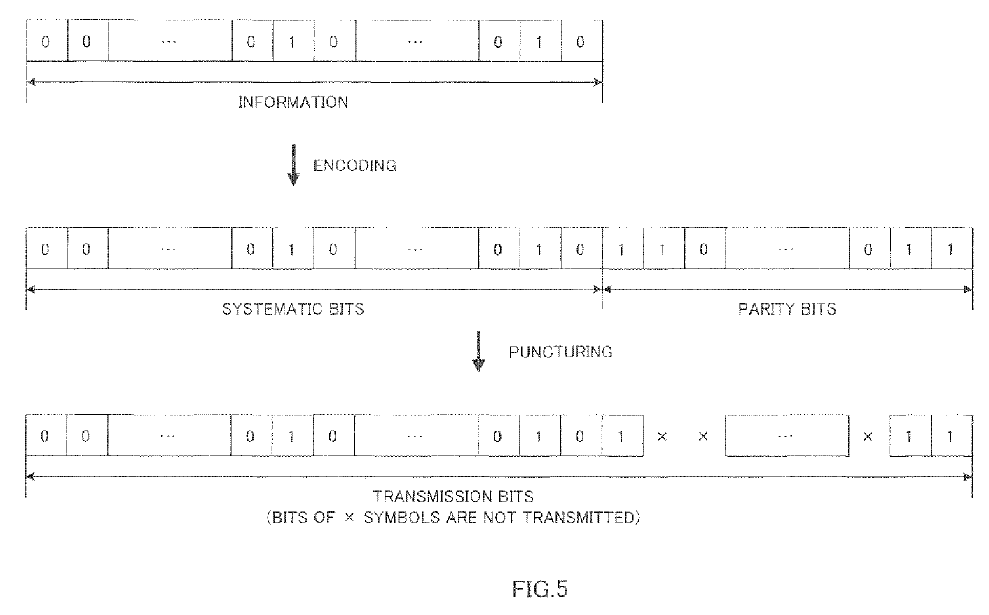

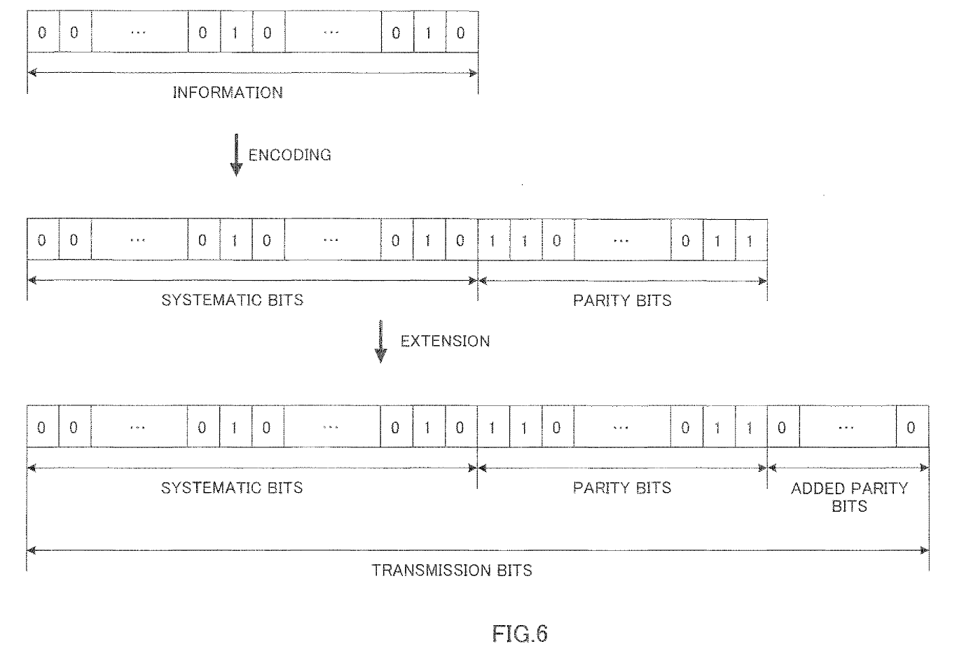

### BEST MODE FOR CARRYING OUT THE INVENTION

An embodiment of the present invention will be explained below in detail with reference to the accompanying drawings. Here, in the following explanation, the processing and functions of unnecessary parts, which are not closely related to the present invention, will be omitted to avoid complicated explanation of the present invention.

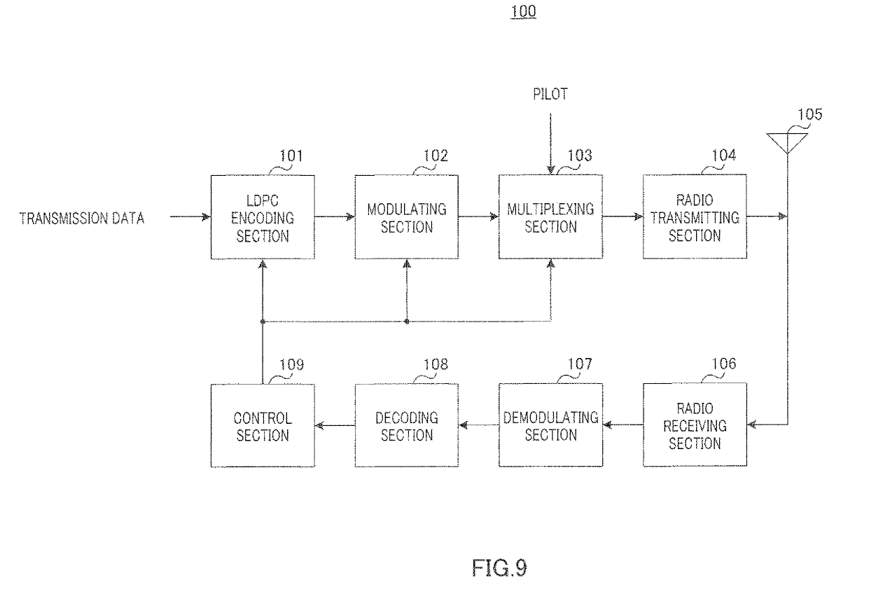

FIG. 9 shows the configuration of transmitting apparatus 100 according to an embodiment.

In transmitting apparatus 100, LDPC encoding section 101 receives as input transmission data. LDPC encoding section 101 performs LDPC encoding of the transmission data using an LDPC code check matrix, to acquire an LDPC codeword comprised of systematic bits and parity bits. Further, LDPC encoding section 101 outputs an encoded bit sequence (i.e. an LDPC encoded bit sequence) extracted from the LDPC codeword according to a coding rate received as input from control section 109, and outputs the encoded bit sequence to modulating section 102. The encoding method in LDPC encoding section 101 will be described later in detail.

Modulating section 102 generates a data symbol by modulating the LDPC encoded bit sequence received as input from LDPC encoding section 101, based on the modulation scheme of an M-ary modulation number received as input from control section 109, and outputs the data symbol to multiplexing section 103.

Multiplexing section 103 multiplexes a pilot signal, the data symbol received as input from modulating section 102 and a control signal received as input from control section 109, and outputs the generated, multiplexed signal to radio transmitting section 104.

Radio transmitting section 104 performs transmission processing such as D/A conversion, amplification and up-conversion on the multiplexed signal, and transmits the result from antenna 105 to receiving apparatus 200. By this means, an LDPC codeword is transmitted to receiving apparatus 200.

On the other hand, radio receiving section 106 receives a control signal transmitted from receiving apparatus 200, via antenna 105, performs reception processing such as down-conversion and A/D conversion on the control signal, and outputs the result to demodulating section 107. This control signal includes a CQI (Channel Quality Indicator) generated in receiving apparatus 200 and ACK/NACK signal. Here, the CQI reported from receiving apparatus 200 may be the average SINR, average SIR or MCS parameters.

Demodulating section 107 demodulates and outputs the control signal to decoding section 108.

Decoding section 108 decodes the control signal and outputs the CQI and ACK/NACK information included in that control signal, to control section 109.

Control section 109 determines the coding rate and M-ary modulation number matching the CQI received as input, and outputs a control signal indicating the determined coding rate and M-ary modulation number, to LDPC encoding section 101, modulating section 102 and multiplexing section 103. Further, control section 109 controls retransmission of transmission data based on an ACK/NACK signal received as input.

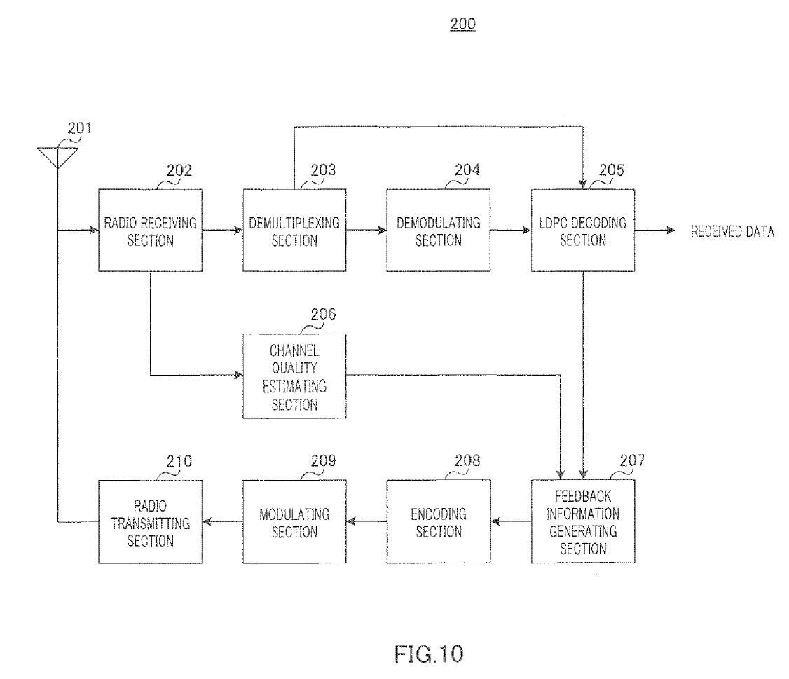

Next, a receiving apparatus according to an embodiment of the present invention will be explained. FIG. 10 shows the configuration of receiving apparatus 200 according to the present embodiment.

In receiving apparatus 200, radio receiving section 202 receives a multiplexed signal transmitted from transmitting apparatus 100 (in FIG. 9), via antenna 201, and performs reception processing such as down-conversion and A/D conversion on the received signal. This received signal includes a pilot signal and data signal (such as a data symbol and control signal). Further, radio receiving section 202 outputs the pilot signal to channel quality estimating section 206 and outputs the data signal to demultiplexing section 203.

Demultiplexing section 203 demultiplexes the data signal into the data symbol and control signal. Further, demultiplexing section 203 outputs the data symbol to demodulating section 204 and outputs the control signal to LDPC decoding section 205.

Demodulating section 204 acquires received data by demodulating the data symbol, and outputs the received data to LDPC decoding section 205.

LDPC decoding section 205 performs LDPC decoding of the data received as input from demodulating section 204, based on the coding rate indicated by the control signal received as input from demultiplexing section 203, to acquire received data. Further, LDPC decoding section 205 performs an error detection of the received data and performs an ACK/NACK detection. Further, LDPC decoding section 205 outputs an ACK/NACK signal as a result of the ACK/NACK detection, to feedback information generating section 207.

On the other hand, channel quality estimating section 206 estimates channel quality (SINR) using the pilot signal received as input from radio receiving section 202. Further, channel quality estimating section 206 outputs the estimated SINR estimation value to feedback information generating section 207.

Feedback information generating section 207 generates a CQI matching the SINR estimation value received as input. Further, feedback information generating section 207 generates a frame for feedback information including the generated CQI and ACK/NACK signal received as input from decoding section 205. Further, feedback information generating section 207 outputs the feedback information to encoding section 208.

Encoding section 208 encodes and outputs the feedback information to modulating section 209.

Modulating section 209 generates a control signal by modulating the feedback information, and outputs the control signal to radio transmitting section 210.

Radio transmitting section 210 performs transmission processing such as D/A conversion, amplification and up-conversion on the control signal, and transmits the result from antenna 201 to transmitting apparatus 100 (in FIG. 9).

Here, the transmitting section of receiving apparatus 200 (formed with encoding section 208, modulating section 209 and radio transmitting section 210) may employ the same configuration as the transmitting section of transmitting apparatus 100, or employ an arbitrary configuration.

Next, the encoding method in LDPC encoding section 101 (in FIG. 9) according to an embodiment of the present invention will be explained in detail. Here, an example case will be explained using a check matrix having a dual diagonal structure. FIG. 11 shows a case where the coding rate is medium (coding rate R=1/2) and a QC LDPC code having a dual diagonal structure is used as the base code. Further, FIG. 11 shows a case where extension is applied to provide LDPC codes of coding rates R=1/3 and R=1/4. Here, assume that the base matrix is formed with m rows and n columns, where, for example, m is 6 and n is 2. Further, the matrix circled by a bold line in the upper left part of the extended check matrix (i.e. extended matrix) in FIG. 11, is the base matrix of six rows and twelve columns. Further, in the base matrix shown in FIG. 11, the part “H₁” represents the systematic bits in an LDPC matrix.

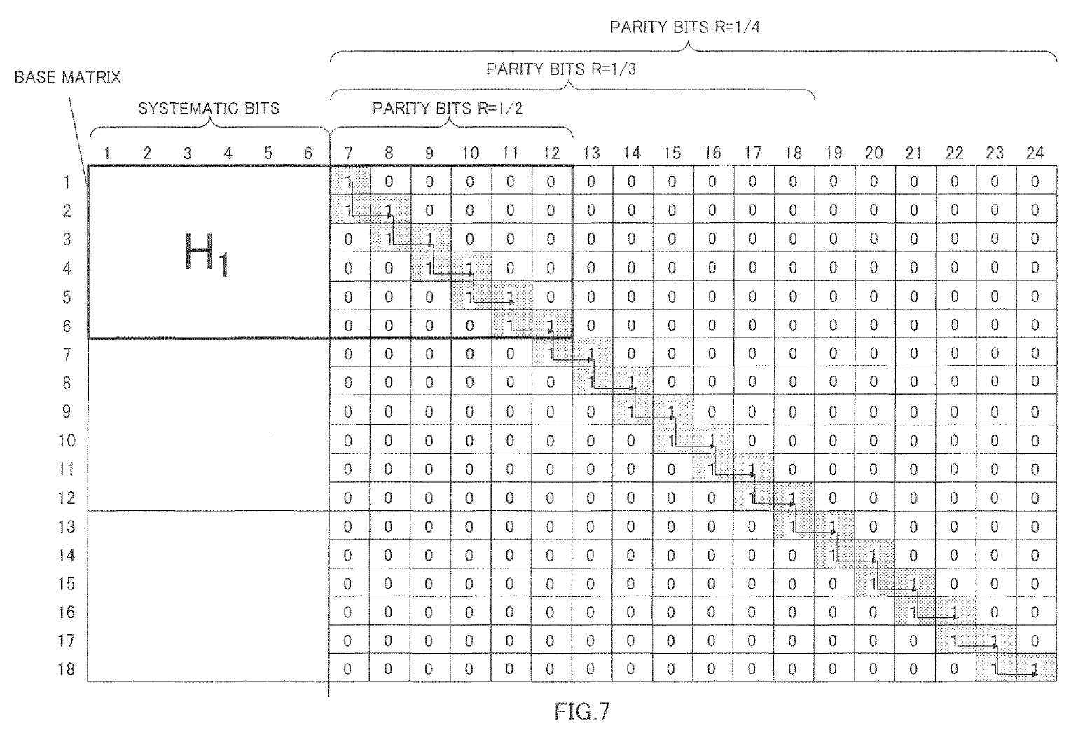

Here, to extend the base matrix, first, LDPC encoding section 101 of transmitting apparatus 100, which makes possible the encoding method of the present invention, sets the coding rate of a code after extension (i.e. extended code) to 1/k (K=3, 4, 5, . . . , k0). Here, 1/k0 is the minimum coding rate of an extended code. Further, LDPC encoding section 101 forms an extended matrix having a dual diagonal structure by extending the base matrix according to the following method. To be more specific, first, LDPC encoding section 101 directly extends the dual diagonal structure of the base matrix shown in FIG. 11, along the dual diagonal. By this means, the extended matrix having the dual diagonal structure shown in FIG. 7 is provided. Next, as shown in FIG. 11, LDPC encoding section 101 shifts the first non-zero element in the part corresponding to the parity bits in the (i*m+1)-th row (where i=0, 1, 2, . . . , k0−2) (i.e. the non-zero element of the lowest column number among the parity bits in the (i*m+1)-th row), leftward to the (n−m+1)-th column (i.e. the first column in the part corresponding to the parity bits) along that row.

Here, in the encoding process of the base code, first, a calculation is performed in the (n−m+1)-th column. Further, after the calculation in the (n−m+1)-th column, calculations are performed sequentially and recursively in the subsequent columns, that is, from the (n−m+2)-th to n-th columns. Thus, in the case where the base code is extended in LDPC encoding section 101 based on the encoding method of the present embodiment, first, sonic non-zero elements on the dual diagonal are shifted to the (n−m+1)-th column in which a calculation was performed. By this means, first, LDPC encoding section 101 calculates the parity bit in the (n−m+1)-th column using the rows in which non-zero elements including the shifted non-zero elements are arranged in the (n−m+1)-th column. Next, using the elements in the (n−m+1)-th column, LDPC encoding section 101 performs a calculation in the (n−m+2)-th column and the (n−m+1+j*m)-th column (where j=1, 2, . . . , k0−2) at the same time. Further, using the (n−m+1+j*m)-th column, LDPC encoding section 101 calculates the parity bits in other columns by the recursive encoding scheme in specific ranges.

To be more specific, as shown in FIG. 11, LDPC encoding section 101 shifts the first non-zero elements in the parity bit parts of the seventh (=1*6+1) row and thirteenth (=2*6+1) row (i.e. the non-zero element in the seventh row, twelfth column, and the non-zero element in the thirteenth row, eighteenth column in FIG. 7), leftward to the seventh row, seventh column and the thirteenth row, seventh column, respectively.

Next, LDPC encoding section 101 sequentially calculates parity bits according to the recursive scheme. To be more specific, in the first time unit, LDPC encoding section 101 calculates the parity bits in the seventh (=n−m+1) column based on the relationships between the elements in the first row and other elements in the check matrix (i.e. check relationship). That is, the parity bits in the seventh (=n−m+1) column are calculated using the check relationship of the elements in the first row (in this case, the first check relationship) as key factors. Here, LDPC encoding section 101 can further acquire the element in the second row, seventh column, by utilizing the characteristics of the dual diagonal structure.

Next, calculating the parity bits in the seventh column in the first time unit gives in advance the elements in the second, seventh and thirteenth rows in the seventh column, so that, in the second time unit, LDPC encoding section 101 simultaneously calculates the parity bits in a plurality of groups (i.e. in the (n−m+2)-th column and the (n−m+1+j*m)-th column) in parallel, based on the check relationships of the non-zero elements in the seventh column. To be more specific, in the second time unit, LDPC encoding section 101 calculates the parity bit in the eighth column using the second row, calculates the parity bit in the thirteenth column using the seventh row and calculates the parity bit in the nineteenth column using the thirteenth row. Also, LDPC encoding section 101 acquires the elements in the third row, eighth column, the eight row, thirteenth column and the fourteenth row, nineteenth column, by utilizing the characteristics of the dual diagonal structure.

Similarly, the elements in the third row, eighth column, the eighth row, thirteenth column and the fourteenth row, nineteenth column are already calculated in the second time unit, so that, in the third time unit, LDPC encoding section 101 simultaneously calculates the parity bits in a plurality of groups in parallel, based on the check relationships of those elements. To be more specific, in the third time unit, LDPC encoding section 101 calculates the parity hit in the ninth column using the third row, calculates the parity bit in the fourteenth column using the eight row and calculates the parity bit in the twentieth column using the fourteenth row. Also, LDPC encoding section 101 acquires the parity bits in the fourth row, ninth column, the ninth row, fourteenth column and the fifteenth row, twentieth column, by utilizing the characteristics of the dual diagonal structure. Afterward, LDPC encoding section 101 sequentially performs the same processing until the parity bits in the tenth to twelfth columns, fifteenth to eighteenth columns and twenty-first to twenty-fourth columns are calculated.

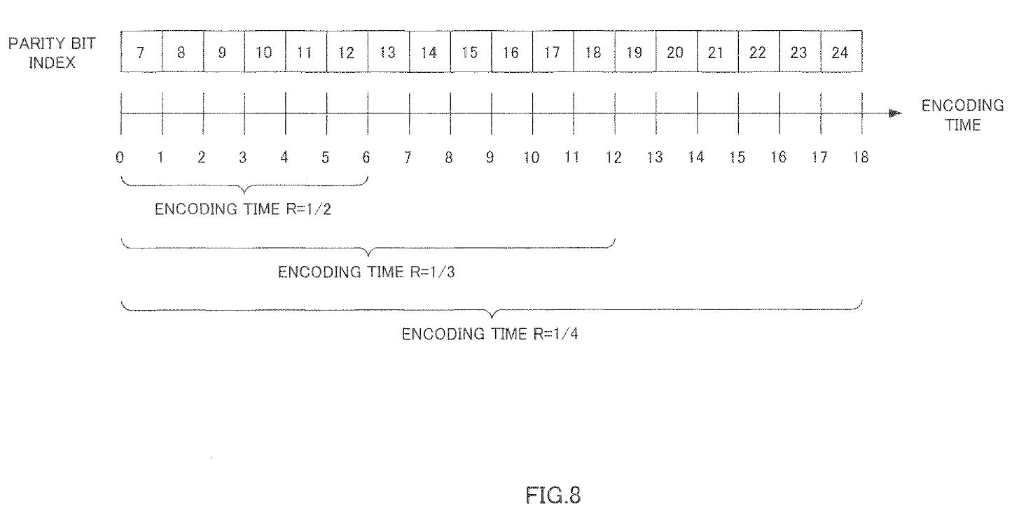

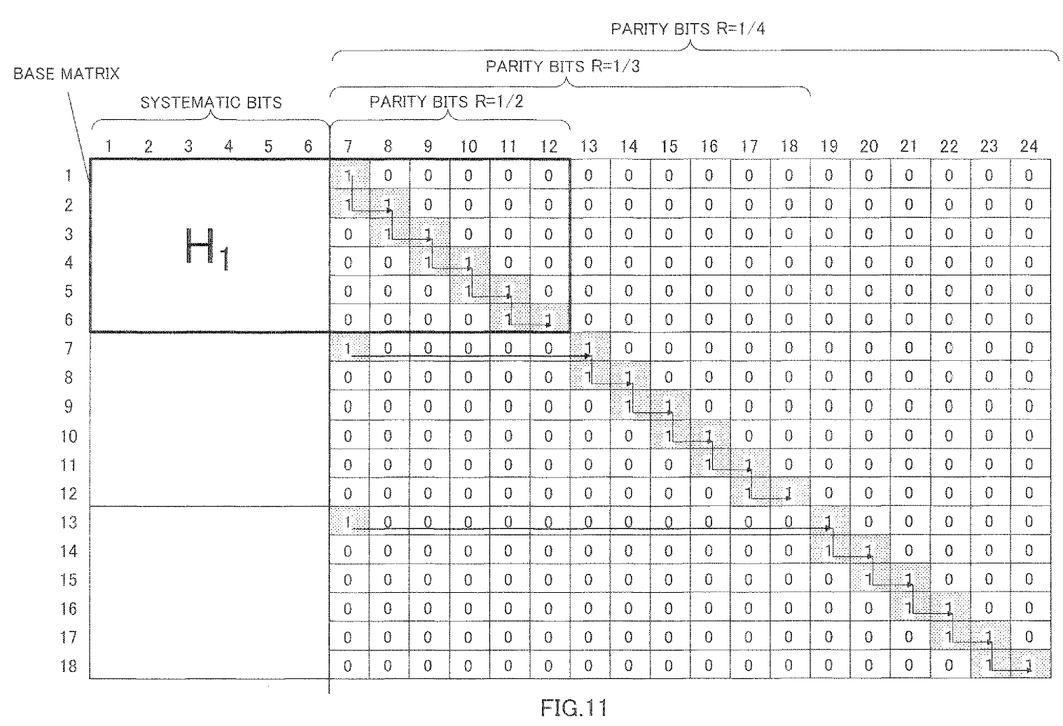

FIG. 12 shows the relationships between the encoding time and generated parity bits in the above encoding method according to the present invention. For example, the parity bit in the seventh column (of parity bit index 7) is calculated in the first time unit (where the encoding timing is 0 in FIG. 12), the parity bits in the eighth, thirteenth and nineteenth columns (of parity bit indices 8, 13 and 19) are simultaneously calculated in the second time unit (where the encoding timing is 1 in FIG. 12), and the parity bits in the ninth, fourteenth and twentieth columns (of parity bit indices 9, 14 and 20) are simultaneously calculated in the third time unit (where the encoding timing is 2 in FIG. 12). The same applies to the fourth to seventh time units (where the encoding timing is 3 to 6). Thus, LDPC encoding section 101 that realizes the encoding method of the present invention changes the dual diagonal structure in an extended matrix having a dual diagonal structure and calculates the parity bits in the extended matrix in parallel with the base matrix, so that it is possible to substantially match the encoding time of extended codes with the encoding time of the base code. To be more specific, as shown in FIG. 12, while it takes the sixth time unit (where the encoding timing is 0 to 5) in the case of the base code (of the coding rate R=½), it takes the seventh time unit (where the encoding time is 0 to 6) in the case of extended codes (of the coding rates R=1/3 and 1/4). Here, in the case of using extension based on an embodiment of the present invention, compared to the method of directly extending a dual diagonal structure (e.g. in FIG. 7 and FIG. 8), it is possible to shorten the encoding time.

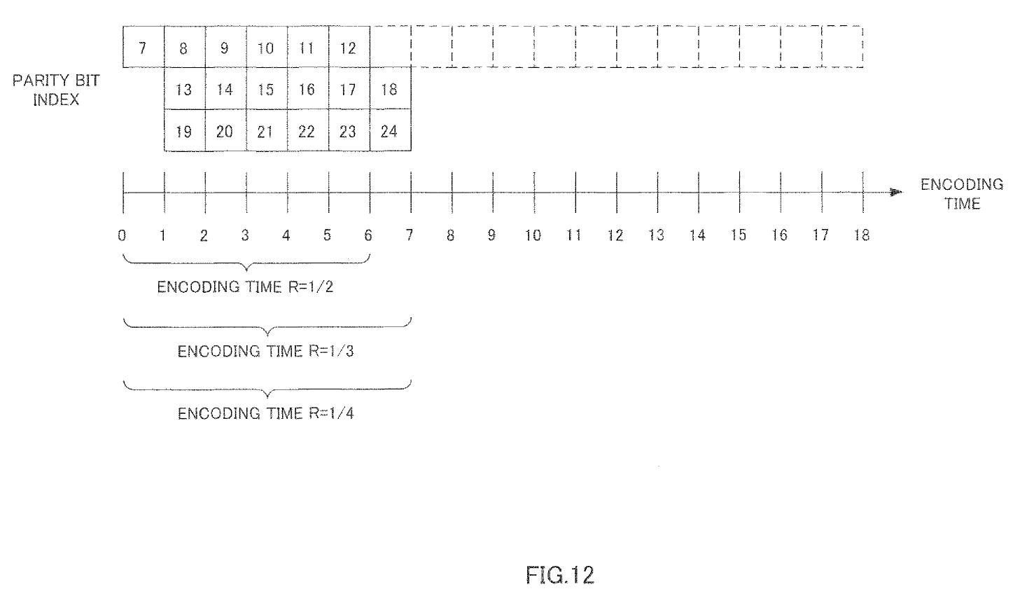

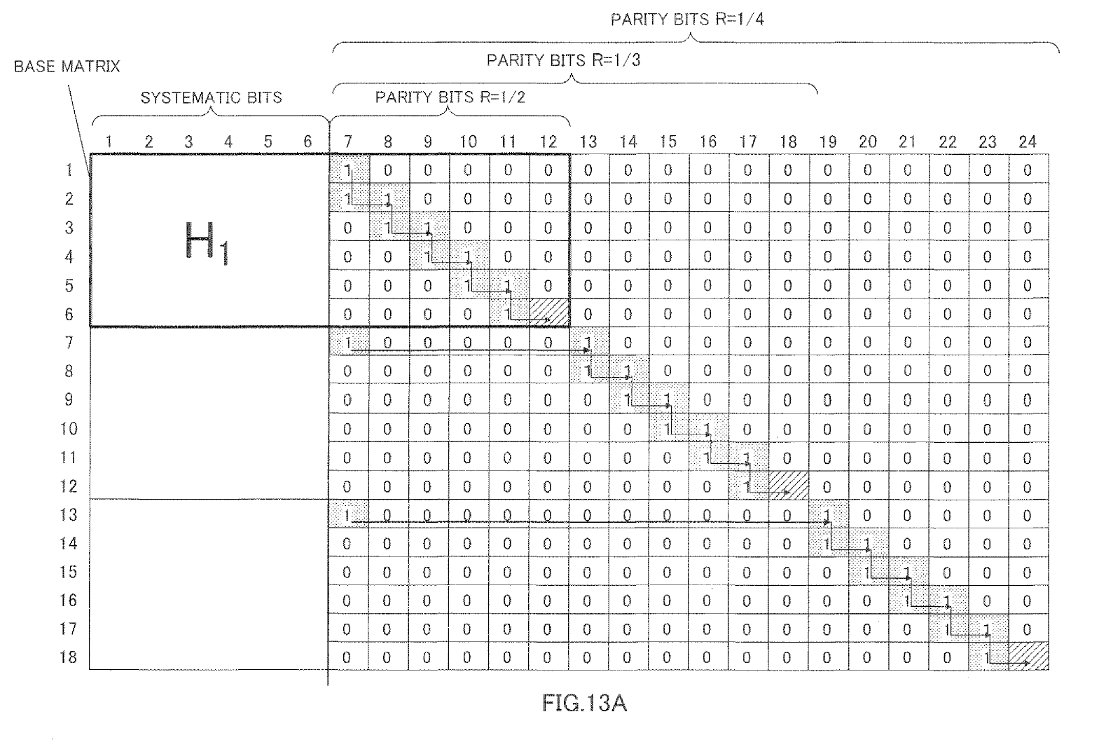

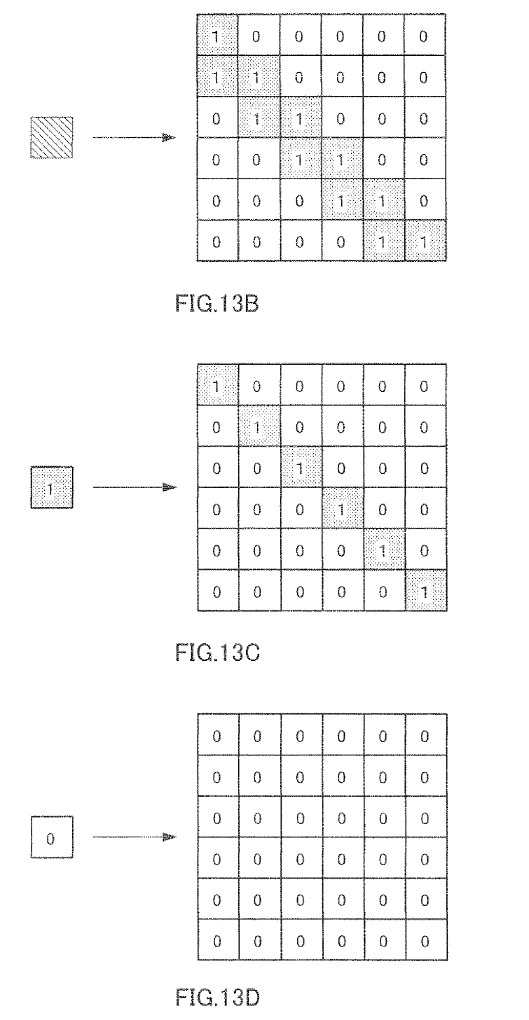

Also, an LDPC code according to the present invention adopts a QC structure, and therefore the elements of the check matrix are each represented by one submatrix. To be more specific, 0's in FIG. 11 represent all-zero submatrixes, and 1's represent identity submatrixes. In an extended matrix according to the present invention in which the dual diagonal structure is changed as shown in FIG. 11, there can be some columns in which the column degree is 1. The presence of a column having column degree 1 may give a negative influence on encoding performance. Therefore, with another embodiment of the present invention, LDPC encoding section 101 changes a base matrix having a dual diagonal structure to an extended matrix, and thereafter replaces submatrixes of column degree 1 using submatrixes having a dual diagonal structure. After the replacement, in the extended matrix, only the final column has column degree 1, and the rest of the columns have column degree 2 or more. FIG. 13A shows a state where, with another embodiment of the present invention, some identity matrixes (in FIG. 13C) are replaced using submatrixes having a dual diagonal structure (FIG. 13B) for reducing the number of columns having column degree 1. Here, in FIG. 13A., the slash parts represent submatrixes having a dual diagonal structure (in FIG. 13B), 1's represent the identity submatrixes (in FIG. 13C) and 0's represent the all-zero submatrixes shown in FIG. 13D. In the above FIG. 11, the column degree is 1 in the twelfth, eighteenth and twenty-fourth columns on the part corresponding to the parity bits in the check matrix, which may give a negative influence on encoding performance. Therefore, to reduce the negative influence on the encoding performance, as shown in FIG. 13A, LDPC encoding section 101 replaces the identity submatrixes in the twelfth, eighteenth and twenty-fourth columns using the submatrixes having a dual diagonal structure shown in FIG. 13B.

Further, using the extended matrix shown in FIG. 13A, LDPC encoding section 101 calculates parity bits in parallel based on the above encoding method of the present invention and thereby shortens the encoding time (i.e. delay time).

Also, instead of using a QC LDPC code having the above dual diagonal structure as a base code, by using an LDPC code having a structure with bidirectional encoding performance (e.g, the encoding structure in the IEEE802.16e standard) as a base code and realizing bidirectional encoding in parallel, it is possible to further shorten the encoding time (i.e. delay time). In this case, LDPC encoding section 101 needs to adjust the extended structure slightly.

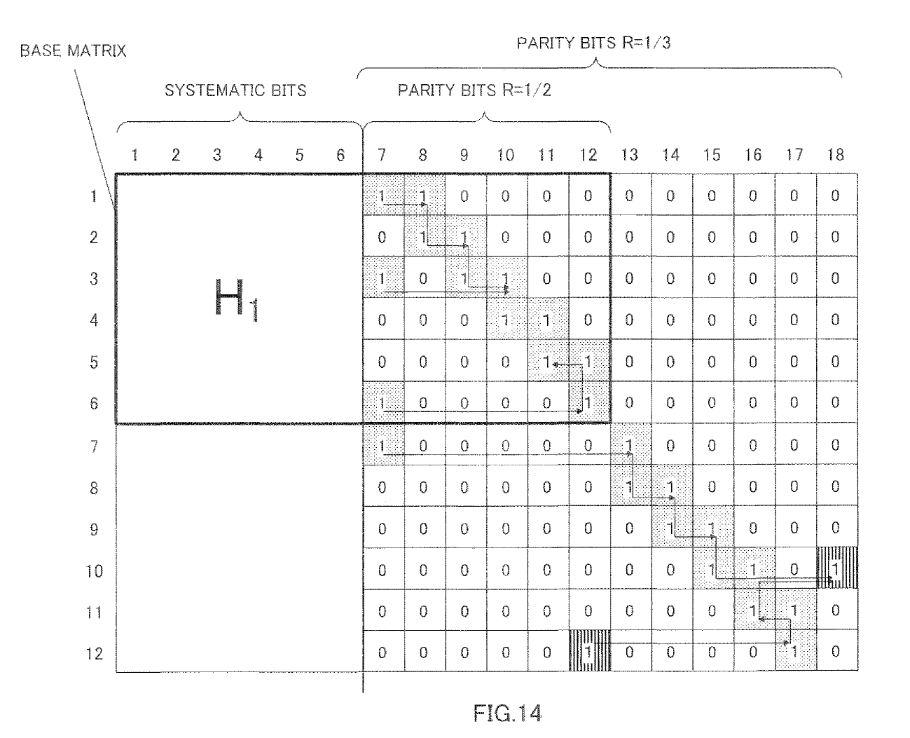

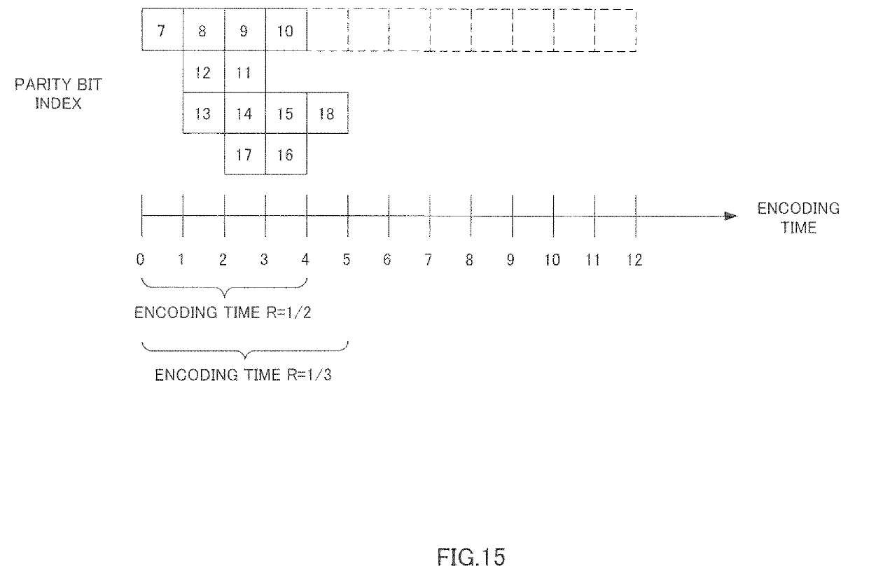

FIG. 14 shows the structure of an extended matrix acquired by extending a base code in the case of using bidirectional encoding. In FIG. 14, the part circled by the bold line is the base matrix (i.e. LDPC matrix) of six rows and twelve columns. Also, in the base matrix, the part “H₁” (formed with the first to sixth rows and first to sixth columns) represents the part corresponding to the systematic bits in the LDPC matrix, and the part in the first to sixth rows and seventh to twelfth columns represents the part corresponding to the parity bit in the base code. LDPC encoding section 101 directly extends the dual diagonal structure of the base matrix along the dual diagonal to form the extended matrix of twelve rows and eighteen columns shown in FIG. 14. Here, to realize bidirectional encoding both in the base code part and in extended subblocks newly generated by extension, LDPC encoding section 101 arranges the identity submatrix (e.g. in FIG. 13C) in the part in the final row of the extended subblock (formed with the seventh to twelfth rows and thirteenth to eighteenth columns in FIG. 14) (i.e. the twelfth row) and final column of the subblock (formed with the seventh to twelfth rows and seventh to twelfth columns in FIG. 14) previous to that extended subblock (i.e. the twelfth column). That is, LDPC encoding section 101 arranges an identity submatrix in the twelfth row, twelfth column in the extended submatrix. Further, if there is a column of column degree 1 in each extended subblock (i.e. if there is only an identity submatrix), LDPC encoding section 101 shifts the identity submatrix upward to the row in the middle of the extended subblock. Here, if there are even number of rows in an extended subblock, LDPC encoding section 101 shifts the identity submatrix to the lower one of the two rows in the middle position. To be more specific, as shown in FIG. 14, LDPC encoding section 101 arranges an identity submatrix in the twelfth row, twelfth column, and shifts the identity submatrix arranged in the twelfth row, eighteenth column to the tenth row, eighteenth column. By this means, it is possible to perform bidirectional encoding in extended subblocks.

The encoding process of bidirectional encoding will be explained using FIG. 14. First, in the first time unit, LDPC encoding section 101 performs addition process in the first to sixth rows of the base code part according to the encoding theory and calculates the elements in the seventh column, that is, key factors. Next, in the second time unit, using the calculated elements in the seventh column (i.e, based on the check relationship of the seventh column), LDPC encoding section 101 calculates the parity bit in the eighth column along the direction indicated by the arrow in the first row in the check matrix shown in FIG. 14. At the same time, LDPC encoding section 101 calculates the parity bit in the twelfth column based on the check relationship of the element in the sixth row, seventh column calculated in the first time unit, and calculates the parity bit in the thirteenth column based on the check relationship of the element in the seventh row, seventh column. In the third time unit, LDPC encoding section 101 can calculate the parity bit in the ninth column along the arrow direction based on the check relationship of the element in the second row, eighth column calculated in the second time unit, calculate the parity bit in the eleventh column along the arrow direction based on the check relationship of the element in the fifth row, twelfth column, and calculate the parity bit in the fourteenth column along the arrow direction based on the cheek relationship of the element in the eighth row, thirteenth column. Further, in the third time unit, LDPC encoding section 101 calculates the parity bit in the seventeenth column based on the check relationship of the element in the twelfth row, twelfth column. Afterward, encoding is performed according to the same encoding method. FIG. 15 shows relationships between the encoding time and generated parity bits in FIG. 14. As shown in FIG. 15, LDPC encoding section 101 can calculate the parity bits in the tenth, fifteenth and sixteenth columns in the fourth time unit (where the encoding time is 3). Also, as shown in FIG. 15, LDPC encoding section 101 can calculate the parity bit in the eighteenth column in the fifth time unit (where the encoding time is 4).

Thus, LDPC encoding section 101 of transmitting apparatus 100 changes the dual diagonal structure as shown in FIG. 15 and calculates the parity bits in extended subblocks and the parity bits in the base matrix part in parallel. By this means, even in the case of performing bidirectional encoding, LDPC encoding section 101 can substantially match the encoding time (i.e. delay time) of extended codes with the encoding time of the base code.

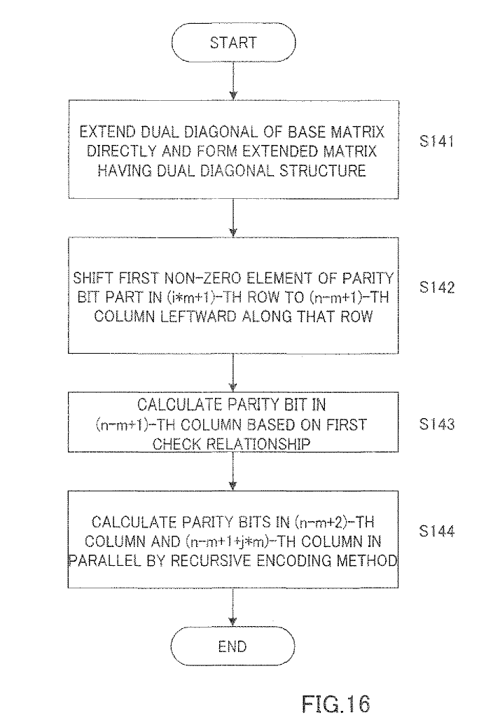

FIG. 16 is a flowchart showing the encoding process of a QC LDPC code having a dual diagonal structure according to the present invention. In step (hereinafter “S”) 141, LDPC encoding section 101 directly extends the dual diagonal structure of a base matrix of m rows and n columns along the dual diagonal, based on the set coding rate 1/k of an extended code (where k=3, 4, 5, k0 holds and 1/k0 is the minimum coding rate of the extended code), to form an extended matrix having the dual diagonal structure. In S142, LDPC encoding section 101 shifts the first non-zero element of the part corresponding to the parity bits in the (i*m+1)-th (where i=1, 2, . . . , k0-2) row leftward to the (n−m+1)-th column along that row, in S143, LDPC encoding section 101 calculates the parity bit in the (n−m+1)-th column using the first check relationship as a key factor. In S144, based on the check relationships of the non-zero elements shifted leftward to the (n−m+1)-th column, LDPC encoding section 101 simultaneously calculates the parity bits in the (n−m+2)-th column and (n−m+1+j*m)-th (where j=1, 2, . . . , k0−2) column in parallel by the recursive encoding method. Afterward, the same processing is sequentially performed until the parity bits in the rest of the columns are calculated.

Thus, according to the present invention, by introducing a plurality of encoding processes in parallel for an LDPC code having a dual diagonal structure, the transmitting apparatus can change the structure of an extended matrix and calculate parity bits in a plurality of groups at the same time. Further, by performing a plurality of encoding processes in parallel in the transmitting apparatus, it is possible to shorten the encoding time. To be more specific, it is possible to substantially match the final encoding time with the encoding time of the base code before extension. Also, the advantage provided by this extension method becomes significant in accordance with the decrease of the coding rate.

The present invention has been described above with the best mode for carrying out the present invention. Here, it is obvious for a skilled person that other various changes, replacement and addition are possible without deviating from the spirit and scope of the present invention. Accordingly, the scope of the present invention should not be understood to be limited only by the above specific embodiment, and is limited by the accompanying claims.

The disclosure of Chinese Patent Application No. 200710186026.X, filed on Nov. 9, 2007, including the specification, drawings and abstract, is incorporated herein by reference in its entirety.

### INDUSTRIAL APPLICABILITY

The encoding method and transmitting apparatus according to the present invention are applicable for use such as mobile communication systems and space communication.

1. An encoding method comprising:
extending a dual diagonal structure of a base matrix of m rows and n columns along a dual diagonal, based on a coding rate 1/k of an extended code (where k=3, 4, 5, . . . , k0 holds, and where 1/k0 is a minimum coding rate of the extended code) set in a check matrix of a low density parity check code, to form an extended matrix having the dual diagonal structure;
shifting a first non-zero element of a parity bit part in a (i*m±1)-th (where i=1, 2, . . . , k0−2) row leftward to a (n−m+1)-th column along that row;
calculating a parity bit in the (n−m+)-th column using a first check relationship as a key factor; and
calculating parity bits in a plurality of groups simultaneously in parallel by a recursive encoding method, based on check relationships of the non-zero elements shifted leftward to the (n−m+1)-th column.

2. The encoding method according to claim 1, wherein the parity bits in the plurality of groups comprise parity bits in a (n−m+2)-th column and (n−m+1+j*m)-th column (where j=1, 2, . . . , k0−2).

3. The encoding method according to claim 1, further comprising:
replacing a submatrix of a column degree of 1 using a submatrix having the dual diagonal structure, if there is the submatrix of the column degree of 1 after extending and converting the base matrix to the extended matrix having the dual diagonal structure.

4. The encoding method according to claim 1, wherein, if the low density parity check code has a bidirectional coding characteristic, after a first parity bit is calculated using the key factor, the parity bits in the plurality of groups are simultaneously calculated by a bidirectional parallel scheme.

5. A transmitting apparatus comprising:
an encoding section that performs low density parity check encoding of transmission data using a check matrix of a low density parity check code, to acquire a codeword comprised of systematic bits and parity bits; and
a transmitting section that transmits the codeword,
wherein the encoding section comprises:
extending a dual diagonal structure of a base matrix of m rows and n columns along a dual diagonal, based on a coding rate 1/k of an extended code (where k=3, 4, 5, . . . , k0 holds and 1/k0 is a minimum coding rate of the extended code) set in the check matrix of the low density parity check code, to form an extended matrix having the dual diagonal structure;
shifting a first non-zero element of a parity bit part in a (i*m+1)-th (where i=1, 2, . . . , k0−2) row leftward to a (n−m+1)-th column along that row;
calculating a parity bit in the (n−m+1)-th column using a first check relationship as a key Factor; and
calculating parity bits in a plurality of groups simultaneously in parallel by a recursive encoding method, based on check relationships of the non-zero elements shifted leftward to the (n−m+1)-th column.
